(19) United States
(12) Patent Application Publication
(10) Pub. No.: US 2007/0023081 A1
(43) Pub. Date: Feb. 1, 2007

(54) Compositionally-graded photovoltaic device and fabrication method, and related articles

(75) Inventors: James Neil Johnson, Schenectady, NY (US); Venkatesan Manivannan, Rexford, NY (US)

Correspondence Address: General Electric Company;GEGR Patent Docket Rm., Bldg. K-1 Rm. 4A59, One Research Circle, Niskayuna, NY, 12309, US

(73) Assignee: General Electric Company

(21) Appl. No.: 11/263,159

(22) Filed: Oct. 31, 2005

Related U.S. Application Data
(60) Provisional application No. 60/704,181, filed on Jul. 28, 2005.

(51) Int. Cl. H01L 31/00; H02N 6/00

(52) U.S. Cl. 136/258; 136/244

(57) ABSTRACT

A semiconductor structure is described, including a semiconductor substrate of one conductivity type; and an amorphous semiconductor layer disposed on at least one of its surfaces. The amorphous semiconductor layer is compositionally graded through its depth, from substantially intrinsic at the interface with the substrate, to substantially conductive at the opposite side. Photovoltaic devices which include such a structure are also disclosed, as are solar modules made from one or more of the devices. Related methods are also described.

This patent application claims the benefit of pending provisional application Ser. No. 60/704,181 (Attorney Dkt. 188359-1), filed on Jul. 28, 2005.

### BACKGROUND OF THE INVENTION

This invention relates generally to the field of semiconductor devices which include a heterojunction, such as a photovoltaic device.

Devices which rely on the presence of a heterojunction are well-known in the art. (As used in this context, a heterojunction is usually formed by contact between a layer or region of one conductivity type with a layer or region of opposite conductivity, e.g., a “p-n” junction). Examples of these devices include thin film transistors, bipolar transistors, and photovoltaic devices (e.g., solar cells).

Photovoltaic devices convert radiation, such as solar, incandescent, or fluorescent radiation, into electrical energy. Sunlight is the typical source of radiation for most devices. The conversion to electrical energy is achieved by the well-known photovoltaic effect. According to this phenomenon, radiation striking a photovoltaic device is absorbed by an active region of the device, generating pairs of electrons and holes, which are sometimes collectively referred to as photo-generated charge carriers. The electrons and holes diffuse, and are collected by the electric field built into the device.

The increasing interest in solar cells as a reliable form of clean, renewable energy has prompted great efforts in increasing the performance of the cells. One primary measurement for such performance is the photoelectric conversion efficiency of the device. Conversion efficiency is usually measured as the amount of electrical current generated by the device, as a proportion of the light energy which contacts its active surface. As documented in the literature, extremely small increases in photoelectric conversion efficiency, e.g., 1% or less, represent very significant advances in photovoltaic technology.

The performance of photovoltaic devices depends in large part on the composition and microstructure of each semiconductor layer. For example, defect states which result from structural imperfections or impurity atoms may reside on the surface or within the bulk of monocrystalline semiconductor layers. Moreover, polycrystalline semiconductor materials may contain randomly-oriented grains, with grain boundaries which induce a large number of bulk and surface defect states.

The presence of various defects of this type can be the source of deleterious effects in the photovoltaic device. For example, many of the charge carriers recombine at the defect sites near the heterojunction, instead of continuing on their intended pathway to one or more collection electrodes. Thus, they become lost as current carriers. Recombination of the charge carriers is one of the chief reasons for decreased photoelectric conversion efficiency.

The negative effects of surface defects can be minimized to some degree by passivation techniques. For example, a layer of intrinsic (i.e., undoped) amorphous semiconductor material can be formed on the surface of the substrate. The presence of this intrinsic layer decreases the recombination of charge carriers at the substrate surface, and thereby improves the performance of the photovoltaic device.

The concept of using this type of intrinsic layer is generally described in U.S. Pat. No. 5,213,628 (Noguchi et al). Noguchi describes a photovoltaic device which includes a monocrystalline or polycrystalline semiconductor layer of a selected conductivity type. A substantially intrinsic layer of 250 Angstroms or less is formed over the substrate. A substantially amorphous layer is formed over the intrinsic layer, having a conductivity opposite that of the substrate, and completing a “semiconductor sandwich structure”. The photovoltaic device is completed by the addition of a light-transparent electrode over the amorphous layer, and a back electrode attached to the underside of the substrate.

The photovoltaic devices described in the Noguchi patent appear to considerably minimize the problem of charge carrier recombination in some situations. For example, the presence of the intrinsic layer at selected thicknesses is said to increase the photoelectric conversion efficiency of the device. Moreover, the concept of passivating the surfaces of semiconductor substrates in this manner has been described in a number of references since the issuance of Noguchi et al. Examples include U.S. Pat. No. 5,648,675 (Terada et al); and U.S. Patent Publications 2002/0069911 A1 (Nakamura et al): 2003/0168660 A1 (Terakawa et al); and 2005/0062041 A1 (Terakawa et al).

While the references mentioned above address the recombination problem to some degree, there are some considerable drawbacks remaining. For example, the presence of the intrinsic layer, while beneficial, results in the formation of yet another interface, i.e., between the intrinsic layer and the overlying amorphous layer. This new interface is yet another site for impurities and spurious contaminants to become trapped and to accumulate, and possibly cause additional recombination of the charge carriers. For example, interruptions between the deposition steps during fabrication of a multilayer structure can provide unwelcome opportunities for the entry of the contaminants. Moreover, abrupt band bending at the interface, due to a change in conductivity, and/or variations in band gap, can lead to a high density of interface states, which is another possible source of recombination.

With some of these concerns in mind, improved photovoltaic devices would be welcome in the art. The devices should minimize the problem of charge-carrier recombination at various interface regions between semiconductor layers. Moreover, the devices should exhibit electrical properties which ensure good photovoltaic performance, e.g., photoelectric conversion efficiency. Furthermore, the devices should be capable of being made efficiently and economically. The fabrication of the devices should eliminate deposition steps which would allow the entry of excessive levels of impurities and other defects.

### BRIEF DESCRIPTION OF THE INVENTION

One embodiment of this invention is directed to a semiconductor structure, comprising:
(a) a semiconductor substrate of one conductivity type; and
(b) an amorphous semiconductor layer disposed on at least one surface of the semiconductor substrate, wherein the amorphous semiconductor layer is compositionally graded through its depth, from substantially intrinsic at the interface with the substrate, to substantially conductive at the opposite side.

A photovoltaic device constitutes another embodiment of the invention. The device comprises the semiconductor structure mentioned above and described below in more detail, and further comprises:
a transparent electrode layer disposed on a surface of the amorphous semiconductor layer, spaced from the substrate; and
an electrode disposed on the opposite surface of the substrate.

In alternative embodiments, a second amorphous semiconductor layer is disposed on a second surface of the semiconductor substrate, substantially opposite the first substrate surface. The second amorphous semiconductor layer is also compositionally graded through its depth, from substantially intrinsic at the interface with the substrate, to substantially conductive at the opposite side. Other elements of the devices are also described below.

An additional embodiment of the invention is directed to a solar module. The module comprises one or more solar cell devices.

Another embodiment relates to a method for making a photovoltaic device, comprising the step of forming an amorphous semiconductor layer over at least a first surface of a semiconductor substrate. The amorphous semiconductor layer is formed by continuously depositing semiconductor material and a dopant over the substrate, while altering the concentration of the dopant, so that the semiconductor layer becomes compositionally-graded through its depth, from substantially intrinsic at the interface with the substrate, to substantially conductive at the opposite side.

Further details regarding the various embodiments are described below.

### BRIEF DESCRIPTION OF THE DRAWINGS

FIG. 1 is a schematic cross-section which depicts the structure of a photovoltaic device according to one embodiment of the present invention.

FIG. 2 is a schematic cross-section which depicts the structure of a photovoltaic device according to another embodiment of the present invention.

### DETAILED DESCRIPTION OF THE INVENTION

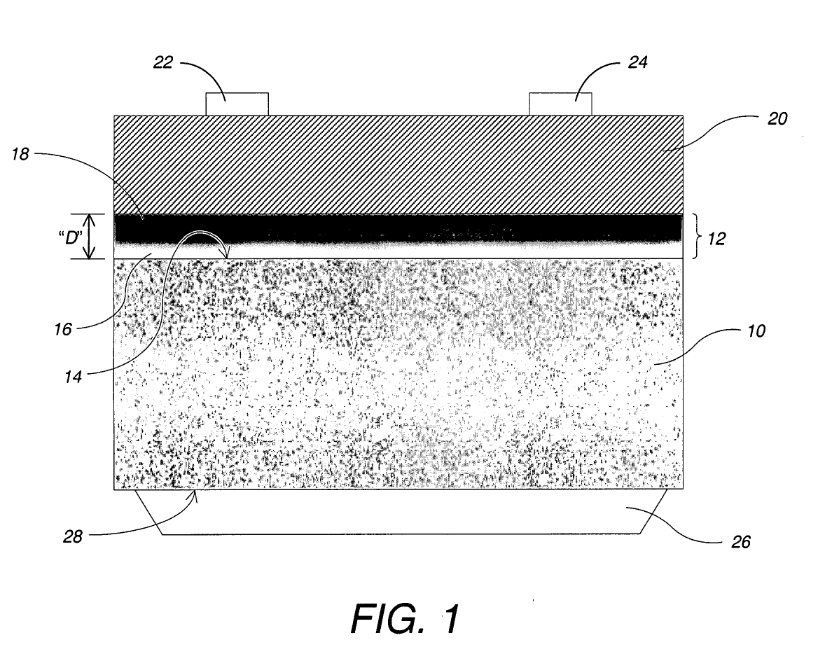

A variety of substrates can be used for most embodiments of this invention. For example, with reference to FIG. 1, substrate 10 can be monocrystalline or polycrystalline. Moreover, the substrate material can be n-type or p-type, depending in part on the electrical requirements for the photovoltaic device. Those skilled in the art are familiar with the details regarding all of these types of silicon substrates.

The substrate is usually subjected to conventional treatment steps, prior to deposition of the other semiconductor layers. For example, the substrate can be cleaned and placed in a vacuum chamber (e.g., a plasma reaction chamber, as described below). The chamber can then be heated to temperatures sufficient to remove any moisture on or within the substrate. Usually, a temperature in the range of about 120-240° C. is sufficient. Sometimes, hydrogen gas is then introduced into the chamber, and the substrate is exposed to a plasma discharge, for additional surface-cleaning. However, many variations on cleaning and pretreatment steps are possible. Usually, these steps are carried out in the chamber used for additional fabrication of the device.

The various semiconductor layers formed over the substrate are usually (though not always) applied by plasma deposition. Many different types of plasma deposition are possible. Non-limiting examples include chemical vapor deposition (CVD); vacuum plasma spray (VPS); low pressure plasma spray (LPPS), plasma-enhanced chemical-vapor deposition (PECVD), radio-frequency plasma-enhanced chemical-vapor deposition (RFPECVD); expanding thermal-plasma chemical-vapor deposition (ETPCVD); electron-cyclotron-resonance plasma-enhanced chemical-vapor deposition (ECRPECVD), inductively coupled plasma-enhanced chemical-vapor deposition (ICPECVD), and air plasma spray (APS). Sputtering techniques could also be used, e.g., reactive sputtering. Moreover, combinations of any of these techniques might also be employed. Those skilled in the art are familiar with the general operating details for all of these deposition techniques. In some preferred embodiments, the various semiconductor layers are formed by a PECVD process.

As mentioned previously, an amorphous semiconductor layer 12 is formed on a top surface 14 of semiconductor substrate 10. Semiconductor layer 12 is compositionally graded, in terms of dopant concentration. In general, the dopant concentration is substantially zero at the interface with the substrate, i.e., portion 16 in FIG. 1. On the opposite side of layer 12, i.e., portion 18, the dopant concentration is at a maximum, in terms of semiconductor conductivity objectives.

As used herein, “compositionally-graded” is meant to describe a gradual change (i.e., a “gradation”) in dopant concentration as a function of the depth (“D”) of semiconductor layer 12. In some embodiments, the gradation is substantially continuous, but this does not always have to be the case. For example, the rate-of-change in concentration may itself vary through the depth, increasing slightly in some regions, and decreasing slightly in others. (However, the overall gradation is always characterized as a decrease in dopant concentration in the direction toward substrate 10). Moreover, in some instances, the dopant concentration may remain constant for some portion of the depth, although that portion would probably be very small. Any and all of these variations in gradations are meant to be encompassed by the term “graded”. The specific dopant concentration profile for a given semiconductor layer will depend on various factors, e.g., type of dopant; electrical requirements for the semiconductor device; the deposition technique for the amorphous layer; as well as its microstructure and thickness.

The dopant concentration is substantially zero at the interface with the substrate, regardless of the particular dopant profile. Thus, an intrinsic region is present at the interface, functioning to prevent recombination of the charge-carriers. At the opposite, upper surface of amorphous layer 12, region 18 is substantially conductive. The specific dopant concentration in that region will depend on the particular requirements for the semiconductor device. As a non-limiting example in the case of a polycrystalline or single crystalline silicon substrate, region 18 will often have a concentration of dopant in the range of about 1×10¹⁶ cm⁻³ to about 1×10²¹ cm⁻³.

The thickness of graded amorphous layer 12 will also depend on various factors, such as the type of dopant employed; the conductivity-type of the substrate; the grading profile; the dopant concentration in region 18; and the optical band gap of layer 12. Usually, the thickness of layer 12 is less than or equal to about 250 Angstroms. In some specific embodiments, graded layer 12 has a thickness in the range of about 30 Angstroms to about 180 Angstroms. The most appropriate thickness in a given situation can be determined without undue effort, e.g., by taking measurements related to the photoelectric conversion efficiency of the device, as well as its open circuit voltage (V_{OC}) and short circuit current (I_{SC}).

The compositional-grading of semiconductor layer 12 can be carried out by various techniques. Usually, grading is accomplished by adjusting the dopant levels during plasma deposition. In a typical embodiment, a silicon precursor gas such as silane (SiH₄) is introduced into the vacuum chamber in which the substrate is situated. A diluting gas such as hydrogen may also be introduced with the silicon precursor gas. Flow rates for the precursor gas can vary considerably, but are typically in the range of about 10 sccm to about 60 sccm. During the initial stages of deposition, no dopant precursors are present. Therefore, region 16 is substantially intrinsic (“undoped”), as mentioned above, thus serving to passivate the surface of substrate 10.

As the deposition process continues, a dopant precursor is added to the plasma mixture. Choice of a precursor will of course depend on the selected dopant, e.g., n-type dopants such as phosphorus (P), arsenic (As), and antimony (Sb); or p-type dopants such as boron (B). Several non-limiting examples of dopant compounds can be provided: diborane gas (B₂H₆) for the p-type dopant, or phosphine (PH₃) for the n-type dopant. The dopant gasses may be in pure form, or they may be diluted with a carrier gas, such as argon, hydrogen, or helium.

The addition of the dopant gas is carefully controlled, to provide the desired doping profile. Those skilled in the art are familiar with gas metering equipment, e.g., mass flow controllers, which can be used to carry out this task. The feed rate for the dopant gas will be selected to substantially match the gradation scheme described above. Thus, in very general terms, the feed rate of the dopant gas will gradually increase during the deposition process. However, many specific changes in feed rate can be programmed into the deposition scheme. Maximum flow rates at the conclusion of this step of the process result in the formation of substantially-conductive region 18, as mentioned previously. Region 18 has a conductivity opposite that of the substrate. Thus, at least a portion of the amorphous semiconductor layer forms a heterojunction with the substrate.

In many embodiments, a transparent conductive film 20 is disposed on amorphous layer 12, on the light-receiving side of the photovoltaic device. Film 20 functions as the front electrode of the device. The transparent conductive film can comprise a variety of materials, such as metal oxides. Non-limiting examples include zinc oxide (ZnO) and indium tin oxide (ITO). Film 20 can be formed by various conventional techniques, such as sputtering or evaporation. Its thickness will depend on various factors, such as the anti-reflective (AR) characteristics of the material. Usually, transparent conductive film 20 will have a thickness in the range of about 200 Angstroms to about 1000 Angstroms.

Metal contacts 22 and 24 are disposed on conductive film 20. The contacts serve as conducting electrodes, and convey the electric current generated by the photovoltaic device to a desired location. They can be formed of a variety of conductive materials, such as silver (Ag), aluminum (Al), copper (Cu), molybdenum (Mo), tungsten (W), and various combinations thereof. Moreover, their shape, size, and number can vary, depending in part on the layer structure and electrical configuration of the device. The metal contacts can be formed by various techniques, e.g., plasma deposition, screen printing; vacuum evaporation (sometimes using a mask); pneumatic dispensing; or direct-write techniques such as ink jet printing.

In one embodiment for this invention, a back electrode 26 is formed on the reverse side 28 of substrate 10. The back electrode performs a function similar to that of contacts 22 and 24, in conveying electric current generated by the photovoltaic device. The back electrode can comprise a wide variety of materials, such as aluminum, silver, molybdenum, titanium, tungsten, and various combinations thereof. Moreover, it can be formed by any conventional technique, such as vacuum evaporation, plasma spraying, sputtering, and the like. As in the case of the other layers, the thickness of the back electrode will depend on various factors. Typically, it has a thickness of about 500 Angstroms to about 3000 Angstroms. In some cases, a buffer layer can be formed between back electrode 26 and the reverse side 28 of substrate 10, e.g., when a diffusion barrier between materials like aluminum and silicon may be desirable.

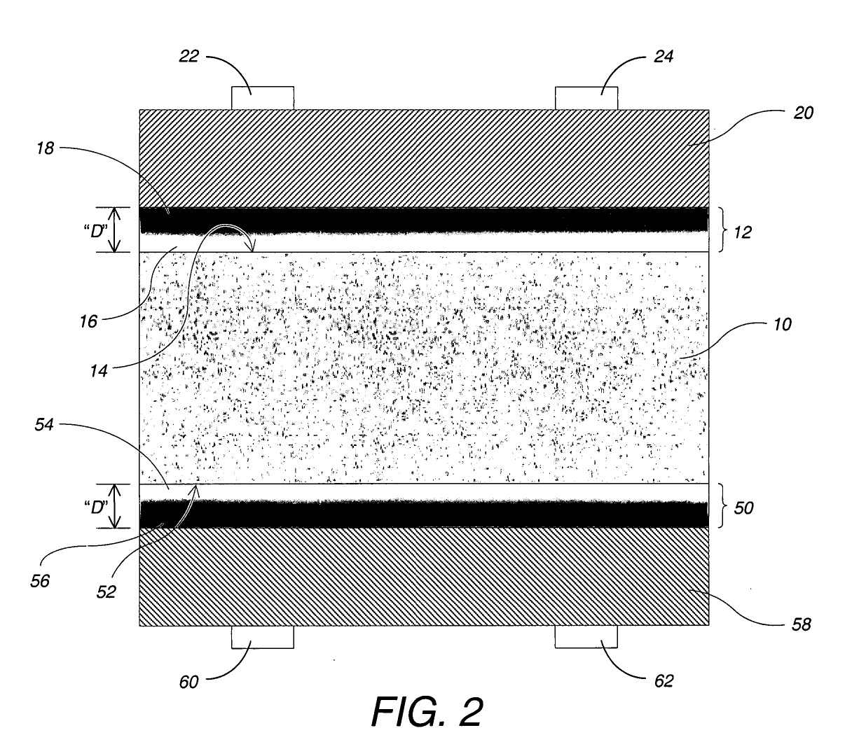

Another embodiment for the semiconductor structure of the present invention is depicted in FIG. 2. In this figure, elements similar or identical to those of FIG. 1 are not labeled, or are provided with the same element numerals. Thus, the compositionally-graded layer 12 is applied over semiconductor substrate 10. Transparent conductive film 20 is again applied over layer 12, followed by the formation of electrical contacts 22 and 24. However, in this embodiment, a compositionally-graded amorphous layer 50 is applied over the back side 52 of substrate 10. As in the case of layer 12, layer 50 is graded, to provide a substantially intrinsic portion 54, and a substantially conductive portion 56. Thus, passivation at the interface between the substrate and layer 50 can be achieved, without the drawbacks associated with the use of separate, discrete intrinsic layers and conductive layers.

The particular gradient (grading pattern) of amorphous layer 50 may differ from the gradient of layer 12, depending in part on the electrical requirements of the device. Grading can be undertaken with the same equipment used for the front side. The thickness of amorphous layer 50 does not have to be identical to the thickness of layer 12, but is also preferably less than or equal to about 250 Angstroms. In some specific embodiments, graded layer 50 has a thickness in the range of about 30 Angstroms to about 180 Angstroms. Again, those skilled in the art will be able to determine the optimum thickness for a given semiconductor structure.

As in the case of the front side of the photovoltaic device, a transparent conductive film 58 is disposed over the back side, i.e., on top of amorphous layer 50. Film 58 can be formed of the same material as transparent conductive film 20, although it may be of a different composition as well. The film is usually a metal oxide such as ZnO or ITO, and is typically applied by plasma deposition. The film usually has a thickness in the range of about 100 Angstroms to about 2000 Angstroms. Following its deposition, metal contacts 60 and 62 can be formed, as described for contacts/electrodes 22 and 24. The contacts need not be of the same size, shape, or composition as the front side contacts, according to the requirements for the device. Moreover, their specific location and number can vary.

In each of the embodiments described herein, the graded layer eliminates at least one interface between discrete multilayers, i.e., interfaces where charge carrier-recombination can occur, as discussed previously. Grading of the dopant concentration through a single layer is thought to provide a continuous variation of localized states in the energy band gap for the particular device, thereby eliminating abrupt band-bending. Moreover, the graded layer can also result in processing advantages during fabrication of the devices, as mentioned previously. For example, interruptions between deposition steps are minimized, so that there is less of an opportunity for the entry of contaminants.

The semiconductor structure described above is sometimes referred to as a “solar cell device”. One or more of these devices can be incorporated into the form of a solar module. For example, a number of the solar cells can be electrically connected to each other, in series or in parallel, to form the module. (Those of ordinary skill in the art are familiar with details regarding the electrical connections, etc). Such a module is capable of much greater energy output than the individual solar cell devices.

Non-limiting examples of solar modules are described in various references, e.g., U.S. Pat. No. 6,667,434 (Morizane et al), which is incorporated herein by reference. The modules can be formed by various techniques. For example, a number of solar cell devices can be sandwiched between glass layers, or between a glass layer and a transparent resin sheet, e.g., those made from EVA (ethylene vinyl acetate). Thus, according to some embodiments of this invention, solar modules contain at least one solar cell device which itself comprises a compositionally-graded amorphous layer adjacent a semiconductor substrate, as described previously. The use of the graded layers can improve device properties like photoelectric conversion efficiency, etc., and thereby improve the overall performance of the solar module.

The Morizane et al reference also describes various other features for some of the solar modules. For example, the patent describes “two-side incidence”-type solar modules in which light can contact both front and rear surfaces of the module. Moreover, the patent describes solar modules which must be extremely moisture-proof (e.g., those used outdoors). In these types of modules, sealing resins can be used to seal the side of each solar cell element. Furthermore, the modules may include various resinous layers which prevent the undesirable diffusion of sodium from nearby glass layers. All of these types of solar modules may incorporate devices which comprise the compositionally-graded amorphous layer (or layers) described herein.

In general, those skilled in the art are familiar with many other details regarding the primary components of the solar modules, e.g., the various substrate materials, backing materials, and module frames. Other details and considerations are also well-known, e.g., wire connections in and out of the module (for example, those leading to an electrical inverter); as well as various module encapsulation techniques.

### EXAMPLES

The examples which follow are merely illustrative, and should not be construed to be any sort of limitation on the scope of the claimed invention.

### Example 1

This example provides a non-limiting illustration of the fabrication of photovoltaic devices according to some embodiments of the present invention. Monocrystalline or polycrystalline semiconductor substrates of one conductivity type are placed in a plasma reaction chamber (for example: a plasma enhanced chemical vapor deposition system). A vacuum pump removes atmospheric gases from the chamber. The substrates to be processed are preheated to about 120 to about 24° C. A hydrogen plasma surface preparation step is performed prior to the deposition of the compositionally graded layer. Hydrogen (H₂) is introduced into the chamber at a flow rate of about 50 to about 500 sccm (standard cubic centimeters per minute). A throttle valve is used to maintain a constant processing pressure in the range of about 200 mTorr to about 800 mTorr. Alternating frequency input power with a power density in the range of about 6 mW/cm² to about 50 mW/cm² range is used to ignite and maintain the plasma. Applied input power can be from about 100 kHz to about 2.45 GHz. Hydrogen plasma surface preparation time is about 1 to about 60 seconds.

At the end of the hydrogen plasma preparation step, silane (SiH₄) is introduced into the process chamber at a flow rate of about 10 sccm to about 60 sccm. This will initiate the deposition of the compositionally-graded single amorphous semiconductor layer. Because no dopant precursors are included in the plasma, the composition of the amorphous layer is initially intrinsic (undoped), thus serving to passivate the surface of the semiconductor substrate. As the deposition process progresses, a dopant precursor is subsequently added to the plasma mixture. Examples of dopant precursors are: B₂H₆, B(CH₃)₃, and PH₃. These may be in pure form or diluted with a carrier gas such as argon, hydrogen or helium. The flow rate of the precursor is increased over the course of the compositionally-graded layer deposition. This forms a gradient in the doping concentration through the single layer. At the conclusion of the graded layer deposition process, concentrations of dopant precursor in the plasma are such that substantially doped amorphous semiconductor properties are achieved.

In one embodiment, an n-type monocrystalline silicon wafer is used as the substrate. After the hydrogen plasma surface preparation (which is optional), the compositionally-graded amorphous layer deposition is started. A mixture of pure hydrogen and silane may be used initially to form intrinsic (undoped) material properties that serve to passivate the substrate surface. Subsequently, a boron-containing precursor is incrementally introduced to the plasma. Since boron acts as a p-type dopant, the amorphous material begins to take on p-type electrical properties. This process proceeds with increasing boron-containing precursor flows until substantially conductive material properties are achieved. As a result, a compositionally-graded layer comprising a boron concentration that continuously varies over its thickness is obtained. The thickness of the graded layer is optimally less than or equal to about 250 Angstroms. This layer will form part of the front structure of the compositionally-graded device.

A similar procedure is followed to passivate the interface with the substrate surface on the opposite side of the device, to form a back surface field (BSF). The difference is that instead of a boron-containing precursor material, a phosphorous-containing precursor is used. Since phosphorous is an n-type dopant, the amorphous material begins to take on n-type electrical properties as the deposition progresses. At the conclusion of the compositionally-graded layer deposition, substantially conductive material properties are achieved. In this case, a compositionally-graded layer comprising a phosphorous concentration that continuously varies over its thickness is obtained. Again, the thickness of the compositionally graded layer is optimally less than or equal to about 250 Angstroms. This layer will form part of the rear structure of the compositionally-graded device.

A transparent conductive oxide (TCO) coating is deposited on the front and rear compositionally-graded layers, in order to form electrodes. These coatings may be, for example, indium tin oxide (ITO) or zinc oxide (ZnO). The TCO properties, including thickness, can be selected such that these layers act as antireflective (AR) coatings. Metal contacts (e.g., Al, Ag, and the like) are formed on the front and rear electrodes, to convey the electric current generated by the device.

While preferred embodiments have been set forth for the purpose of illustration, the foregoing description should not be deemed to be a limitation on the scope of the invention. Accordingly, various modifications, adaptations, and alternatives may occur to one skilled in the art without departing from the spirit and scope of the claimed inventive concept. All of the patents, patent applications (including provisional applications), articles, and texts which are mentioned above are incorporated herein by reference.

What is claimed:

1. A semiconductor structure, comprising:
(a) a semiconductor substrate of one conductivity type; and
(b) an amorphous semiconductor layer disposed on at least one surface of the semiconductor substrate, wherein the amorphous semiconductor layer is compositionally graded through its depth, from substantially intrinsic at the interface with the substrate, to substantially conductive at the opposite side.

2. The semiconductor structure of claim 1, wherein the substrate is monocrystalline or polycrystalline; and is n-type or p-type.

3. The semiconductor structure of claim 2, wherein the amorphous semiconductor layer of component (b) has a thickness less than about 250 Angstroms.

4. The semiconductor structure of claim 3, wherein the amorphous semiconductor layer of component (b) has a thickness in the range of about 30 Angstroms to about 180 Angstroms.

5. The semiconductor structure of claim 1, wherein the amorphous semiconductor layer comprises n-type or p-type impurities which provide a selected conductivity.

6. The semiconductor structure of claim 5, wherein the n-type impurities comprise phosphorous; and the p-type impurities comprise boron.

7. The semiconductor structure of claim 5, wherein the selected conductivity of the amorphous semiconductor layer is opposite that of the substrate.

8. The semiconductor structure of claim 7, wherein at least a portion of the amorphous semiconductor layer forms a heterojunction with the substrate.

9. The semiconductor structure of claim 1, wherein the concentration of impurities at the interface with the substrate is substantially zero; and the concentration of impurities at the opposite side is in the range of about 1×10¹⁶ cm⁻³ to about 1×10²¹ cm⁻³.

10. A photovoltaic device comprising the semiconductor structure of claim 1, and further comprising:
a transparent electrode layer disposed on a surface of the amorphous semiconductor layer, spaced from the substrate; and
an electrode disposed on the opposite surface of the substrate.

11. The photovoltaic device of claim 10, further comprising at least one collecting electrode disposed on the transparent electrode layer.

12. A semiconductor structure, comprising:
(a) a semiconductor substrate of one conductivity type;
(b) a first amorphous semiconductor layer disposed on a first surface of the semiconductor substrate, wherein the amorphous semiconductor layer is compositionally graded through its depth, from substantially intrinsic at the interface with the substrate, to substantially conductive at the opposite side;
(c) a first transparent electrode layer disposed on the surface of the first amorphous semiconductor layer;
(d) at least one electrical contact disposed on the first transparent electrode layer;
(e) a second amorphous semiconductor layer disposed on a second surface of the semiconductor substrate, substantially opposite the first substrate surface, wherein the second amorphous semiconductor layer is compositionally graded through its depth, from substantially intrinsic at the interface with the substrate, to substantially conductive at the opposite side;
(f) a second transparent electrode layer disposed on the surface of the second amorphous semiconductor layer; and
(g) at least one electrical contact disposed on the second transparent electrode layer.

13. A solar module, comprising one or more solar cell devices, wherein at least one of the solar cell devices comprises:
(i) a semiconductor substrate of one conductivity type; and
(ii) an amorphous semiconductor layer disposed on at least one surface of the semiconductor substrate, wherein the amorphous semiconductor layer is compositionally graded through its depth, from substantially intrinsic at the interface with the substrate, to substantially conductive at the opposite side.

14. A method for making a photovoltaic device, comprising the step of forming an amorphous semiconductor layer over at least a first surface of a semiconductor substrate, wherein the amorphous semiconductor layer is formed by continuously depositing semiconductor material and a dopant over the substrate, while altering the concentration of the dopant, so that the semiconductor layer becomes compositionally-graded through its depth, from substantially intrinsic at the interface with the substrate, to substantially conductive at the opposite side.

15. The method of claim 14, wherein the formation of the amorphous semiconductor layer is carried out by a plasma deposition process.

16. The method of claim 15, wherein the plasma deposition process is plasma-enhanced chemical-vapor deposition (PECVD).

17. The method of claim 14, wherein two compositionally-graded amorphous semiconductor layers are formed, by depositing semiconductor material over two surfaces of the semiconductor substrate.

18. The method of claim 14, further comprising the step of forming a transparent electrode layer over the surface of the amorphous semiconductor layer, followed by the formation of at least one metal contact on the transparent electrode layer.

19. The method of claim 18, further comprising the step of providing at least one electrode on a second surface of the semiconductor substrate which is opposite the first surface.
